(19) United States
(12) Patent Application Publication
(10) Pub. No.: US 2025/0109484 A1
(43) Pub. Date: Apr. 3, 2025

(54) WEAR-RESISTANT COATING OF AlTiN-WS2 AND PREPARATION METHOD THEREOF

(71) Applicants: Taizhou University, Taizhou (CN); Wenling Gonglian Measuring&Cutting Tool Technology Service Center Co., Ltd, Taizhou (CN); Wenling Research Institute of Taizhou University, Taizhou (CN)

(72) Inventors: Ping Zhang, Taizhou (CN); Puyou Ying, Taizhou (CN); Jianbo Wu, Taizhou (CN); Vladimir Levchenko, Taizhou (CN); Tao Yang, Taizhou (CN); Changhong Lin, Taizhou (CN); Jian Wu, Taizhou (CN)

(21) Appl. No.: 18/621,063

(22) Filed: Mar. 28, 2024

(30) Foreign Application Priority Data
Sep. 28, 2023 (CN) 202311278867.9

(51) Int. Cl. C23C 14/35; C23C 14/02; C23C 14/06

(52) U.S. Cl. CPC C23C 14/35; C23C 14/021; C23C 14/022; C23C 14/0617; C23C 14/0623; C23C 14/325; C23C 14/3485; C23C 28/042; C23C 28/34; C23C 28/347

(57) ABSTRACT

A wear-resistant coating with a low friction coefficient of aluminum titanium nitride-tungsten disulfide (AlTiN—WS₂) and a preparation method are provided. The preparation method includes: (1) performing a titanium ion cleaning on a preprocessed substrate by using a titanium ion arc target to obtain a cleaned substrate; (2) depositing a titanium transition coating on the cleaned substrate by using a multi-arc ion plating to obtain a deposited substrate; (3) depositing an aluminum titanium nitride (AlTiN) coating on the deposited substrate by using an AlTi alloy ion arc target to obtain an AlTiN coating substrate; and (4) depositing a titanium coating and a tungsten disulfide (WS₂) coating by using a high power impulse magnetron sputtering (HiPIMS) to obtain the wear-resistant coating of AlTiN—WS₂. The wear-resistant coating is prepared by pre-depositing the AlTiN solid coating using the multi-arc ion plating, and followed by depositing the WS₂ solid lubrication coating using HiPIMS.

### TECHNICAL FIELD

The disclosure relates to the technical field of lubrication coatings, and particularly to a wear-resistant coating with a low friction coefficient of aluminum titanium nitride-tungsten disulfide (AlTiN—WS₂) and a preparation method thereof.

### BACKGROUND

Hard coatings mainly include nitride coatings, carbide coatings, oxide coatings, and boride coatings. Currently, researches on nitrides are relatively mature and widely used. The early commonly used nitride coatings mainly include titanium nitride (TiN) coatings and chromium nitride (CrN) coatings. Compared with the TiN coatings, the CrN coatings have better friction performance and lower friction coefficient, making their applications more advantageous. However, the performance of the CrN coatings suffer a sharp decrease in tool temperature after exceeding 650° C., which are unsuitable for the high-temperature cutting.

In recent years, with the demand for high-speed and efficient cutting, there has been an increasing demand for high-temperature oxidation resistance of coatings. Usually, the addition of aluminum (Al) can significantly improve the high-temperature oxidation resistance of coatings. Researches have shown that the oxidation temperature of the aluminum titanium nitride (TiAlN) coating obtained by adding Al in the TiN coating can be increased to 800° C. compared to the binary nitride coatings. This is mainly because the Al in the coating can form a thermal insulation protective layer of aluminium oxide (Al₂O₃) in high-temperature environments, preventing further high-temperature oxidation of the coating. However, the latest research shows that the oxide layer of Al₂O₃ formed on the TiAlN coating is not dense, and there are scattered particles of Al₂O₃ on the surface of the TiAlN coating. In contrast, chromium (Cr) has a higher melting point than Ti, and using Cr instead of Ti in the aluminum chromium nitride (AlCrN) coatings can improve their high-temperature oxidation resistance compared to the TiAlN coatings. Although the coatings containing Al has improved in hardness and high-temperature resistance, the friction coefficients of the coatings containing Al are still very high. To address this issue, the friction coefficients can be reduced by doping molybdenum (Mo) and vanadium (V). Overall, the minimum friction coefficient of hard nitride coatings on steel is in a range of 0.4 and 0.5, and the friction coefficient is still relatively large and cannot be directly used.

Tungsten disulfide (WS₂), as a transition metal sulfide with a layered structure, has excellent thermal stability, oxidation resistance, and a wide operating temperature range, and is a solid lubrication material with broad application prospects. Especially in some special application situations, such as environments with strong pressure, high load, or radiation and corrosion, the performance of WS₂ is particularly outstanding, making it very suitable as a new type of lubrication material. However, the pure WS₂ coating prepared by magnetron sputtering has a soft texture and is prone to losing its lubrication performance during friction. In view of this defect, researchers improved the structural morphology and properties of the WS₂ coatings by incorporating oxides such as titanium dioxide (TiO₂) and zinc oxide (ZnO), and elements such as Ti, Cr, Ni, Al, Zr, Cu and Ni—Co. Researches have shown that after doping, the composite coating structure becomes denser, the surface becomes smoother, the adhesion with the substrate is stronger, and the hardness, friction and wear resistance, oxidation resistance, and humidity resistance of the composite coating are also improved. However, the hardness of the solid lubrication coatings based on WS₂ is generally not high, making them suitable for application under low loads, and their wear resistance still needs to be improved under high loads.

### SUMMARY

In response to the shortcomings in the related art, the disclosure provides a preparation method for a wear-resistant coating with a low friction coefficient of aluminum titanium nitride-tungsten disulfide (AlTiN—WS₂). The preparation method uses a multi-arc ion plating to pre-deposit an aluminum titanium nitride (AlTiN) hard coating to obtain an AlTiN coating substrate, and then uses high power pulse magnetron sputtering (HiPIMS) to deposit a WS₂ solid lubrication coating on the AlTiN coating substrate, thereby to obtain a wear-resistant coating with a low friction coefficient.

To achieve the above objectives, the disclosure is implemented through the following technical solutions.

In an aspect, a preparation method for a wear-resistant coating with a low friction coefficient of AlTiN—WS₂ is provided and includes the following steps:
(1) performing a titanium ion cleaning on a preprocessed substrate by using a titanium ion arc target to obtain a cleaned substrate;
(2) depositing a titanium transition coating on the cleaned substrate by using a multi-arc ion plating to obtain a deposited substrate;
(3) depositing an AlTiN coating on the deposited substrate by using an AlTi alloy ion arc target to obtain an AlTiN coating substrate; and
(4) depositing a titanium coating and a tungsten disulfide (WS₂) coating respectively on the AlTiN coating substrate by using an impulse magnetron sputtering to obtain the wear-resistant coating of AlTiN—WS₂.

In an embodiment, the step (1) specifically includes: putting the preprocessed substrate into a vacuum chamber, then extracting pressure of the vacuum chamber below 7×10⁻³ pascals (Pa), after the extracting, heating the vacuum chamber to stabilize a temperature of the vacuum chamber in a range of 100-300° C., followed by using the titanium ion arc target with a set target current of 60 amperes (A), injecting an argon gas in a range of 50-100 standard cubic centimeter per minute (sccm) and setting a bias voltage of the preprocessed substrate in a range of 600-800 voltages (V), and performing the titanium ion cleaning on the preprocessed substrate for 3-5 minutes (min) to obtain the cleaned substrate.

In an embodiment, the step (2) further includes: after performing the titanium ion cleaning, setting a bias voltage of the cleaned substrate in a range of 100-300 V, followed by depositing the titanium transition coating with a thickness in a range of 100-500 nanometers (nm) on the cleaned substrate by using the multi-arc ion plating to obtain the deposited substrate.

In an embodiment, the step (3) further includes: using the AlTi alloy ion arc target, injecting an argon gas in a range of 20-120 sccm and a nitrogen gas in a range of 200-400 sccm, and setting a bias voltage of the deposited substrate in a range of 50-150 V, and depositing the AlTiN coating in a form of a metal nitride coating with a thickness in a range of 1-3 micrometers (μm) to obtain the AlTiN coating substrate.

In an embodiment, the step (4) further includes: after the step (3), reducing a temperature of a vacuum chamber to 100° C., stopping injecting a nitrogen gas, injecting an argon gas in a range of 200-300 sccm, and using the impulse magnetron sputtering to deposit the titanium coating with a thickness in a range of 50-200 nm, followed by using the high power impulse magnetron sputtering to deposit the WS₂ coating in a form of a solid lubrication coating to obtain the wear-resistant coating of AlTiN—WS₂.

In another aspect, a wear-resistant coating with a low friction coefficient of AlTiN—WS₂ prepared by the preparation method mentioned above is provided.

In still another aspect, an application method of the wear-resistant coating of AlTiN—WS₂ prepared by the above preparation method is used on needle rods of a sewing machine.

The beneficial effects of the disclosure are as follows.

The wear-resistant coating with the low friction coefficient of AlTiN—WS₂ and the composite deposition method (i.e., preparation method) thereof are provided. The wear-resistant coating with the low friction coefficient of AlTiN—WS₂ can be prepared by using the preparation method, which greatly reduce a wear rate of the AlTiN coating. The wear-resistant coating with a low friction coefficient of AlTiN—WS₂ prepared by using the preparation method can be used on the needle rods of the sewing machine, which can break through the limitation of motion mechanisms of the high-end and high-speed sewing machine using diamond like carbon (DLC) coatings. Based on the preparation method, the wear-resistant coating with the lower friction coefficient can be prepared on motion structures such as the needle rods of the sewing machine.

### BRIEF DESCRIPTION OF DRAWINGS

FIG. 1 illustrates a cross-sectional scanning electron microscope (SEM) image of an aluminum titanium nitride-tungsten disulfide (AlTiN—WS₂) composite coating prepared in embodiment 1.

FIG. 2 illustrates a friction coefficient curve diagram of an aluminum titanium nitride (AlTiN) coating prepared in comparative example 1 and the AlTiN—WS₂ composite coating prepared in the embodiment 1 after friction.

FIG. 3 illustrates a grinding scar morphology diagram of the AlTiN coating prepared in the comparative example 1 and the AlTiN—WS₂ composite coating prepared in the embodiment 1.

FIG. 4 illustrates a wear rate diagram of the AlTiN coating prepared in the comparative example 1 and the AlTiN—WS₂ composite coating prepared in the embodiment 1.

FIG. 5 illustrates a working time diagram of a titanium (Ti) target during a titanium ion cleaning.

FIG. 6 illustrates a photo of a needle rod of a sewing machine.

FIG. 7 illustrates a photo of needle rods after running-in tests in embodiment 2, comparative example 2 and comparative example 3, where 1 represents a needle rod after the running-in test in the embodiment 2, 2 represents a needle rod after the running-in test in the comparative example 2, and 3 represents a needle rod after the running-in test in the comparative example 3.

FIG. 8 illustrates a photo of local wears after the running-in tests in the embodiment 2, the comparative example 2 and the comparative example 3, where 1 represents a local wear of a needle rod corresponding to an upper sleeve after the running-in test in the embodiment 2, 2 represents a local wear of a needle rod corresponding to the upper sleeve after the running-in test in the comparative example 2, 3 represents a local wear of a needle rod corresponding to the upper sleeve after the running-in test in the comparative example 3, 4 represents a local wear of a needle rod corresponding to a lower sleeve after the running-in test in the embodiment 2, and 5 represents a local wear of a needle rod corresponding to a lower sleeve after the running-in test in the comparative example 2, 6 represents a local wear of a needle rod corresponding to a lower sleeve after the running-in test in the comparative example 3.

FIG. 9 illustrates a wear quality diagram after running-in tests in the embodiment 2, the comparative example 2 and the comparative example 3.

FIG. 10 illustrates a wear rate diagram of the AlTiN coating prepared in the comparative example 1 and the AlTiN—WS₂ composite coating prepared in the embodiment 1 obtained under a condition with a load of 5 Newton (N) and a relative friction frequency of 2 hertz (Hz).

FIG. 11 illustrates a coefficient of friction diagram of the AlTiN coating prepared in the comparative example 1 and the AlTiN—WS₂ composite coating prepared in the embodiment 1 obtained under a condition with a load of 5 N and a relative friction frequency of 2 Hz.

### DETAILED DESCRIPTION OF EMBODIMENTS

The following will provide a clear and complete description of the technical solution in the embodiments of the disclosure, in conjunction with the attached drawings. Apparently, the described embodiments are only a part of the embodiments of the disclosure, not all of them. Based on the embodiments in the disclosure, all other embodiments obtained by those skilled in the art without creative labor fall within the scope of protection of the disclosure.

If not specifically noted, the technical means used in the embodiments are conventional means well-known to those skilled in the art.

Specifically, a preparation method for a wear-resistant coating of AlTiN—WS₂ is provided and includes the following steps.

Step (1), a titanium ion cleaning is performed on a preprocessed substrate by using a titanium ion arc target to obtain a cleaned substrate.

A process obtaining the preprocessed substrate is as follows: a substrate to be preprocessed is put into an acetone solution and an ethyl alcohol solution individually to ultrasonically wash for 10-30 minutes (min) to remove oil stain on the surface of the substrate to be preprocessed, thereby obtaining a washed substrate, then the washed substrate is ultrasonically washed by using a deionized water for 4-6 times, followed by drying to obtain the preprocessed substrate, and the preprocessed substrate is disposed on a sample holder.

The sample holder provided with the preprocessed substrate is put into a vacuum chamber, then pressure of the vacuum chamber is extracted below 7×10⁻³ pascals (Pa). After the extracting, the vacuum chamber is heat to stabilize a temperature of the vacuum chamber in a range of 100-300° C. Then, using the titanium ion arc target, a target current is set to 60 amperes (A), an argon gas is injected at 50-100 standard cubic centimeter per minute (sccm) and a bias voltage of the preprocessed substrate is set in a range of 600-800 voltages (V). In this situation, the titanium ion cleaning is performed on the preprocessed substrate to obtain the cleaned substrate. In order to avoid the substrate temperature is too high in the metal ion cleaning, the working time of titanium target is set, the titanium target is opened for 1 minute (min), closed for 1-3 min, and the total cleaning time is 3-5 min, thereby removing impurities from the surface of the substrate and improving the adhesion strength of the substrate.

Step (2), a titanium transition coating is deposited on the cleaned substrate by using a multi-arc ion plating to obtain a deposited substrate.

A specific process of the step (2) is as follow: after performing the titanium ion cleaning, a bias voltage of the cleaned substrate is set in a range of 100-300 V, a current of the titanium ion arc target is set to 60 A, followed by depositing the titanium transition coating with a thickness in a range of 100-500 nanometers (nm) on the cleaned substrate by using a multi-arc ion plating to obtain the deposited substrate or depositing the titanium transition coating by using the multi-arc ion plating for 30 min to obtain the deposited substrate.

Step (3), an aluminum titanium nitride (AlTiN) coating is deposited on the deposited substrate by using an AlTi alloy ion arc target to obtain an AlTiN coating substrate.

A specific process of the step (3) is as follow: the AlTi alloy ion arc target is used, and a target current is set to 60 A, the argon gas in a range of 20-120 sccm and a nitrogen gas in a range of 200-400 sccm are injected into the vacuum chamber, and a bias voltage of the deposited substrate is set in a range of 50-150 V, and the AlTiN coating is deposited on the deposited substrate in a form of metal nitride coating with a thickness in a range of 1-3 micrometers (m) to obtain the AlTiN coating substrate or the AlTiN coating is deposited on the deposited substrate for 120-180 min to obtain the AlTiN coating substrate.

Step (4), a titanium coating and a tungsten disulfide (WS₂) coating are deposited respectively on the AlTiN coating substrate by using a high power impulse magnetron sputtering to obtain the wear-resistant coating of aluminum titanium nitride-tungsten disulfide (AlTiN—WS₂) as a sample. After obtaining the sample, the sample holder is removed from the vacuum chamber when the temperature drops below 60° C.

A specific process of the step (4) is as follow: the temperature of the vacuum chamber is reduced to 100° C., the nitrogen gas is stopped injecting, the argon gas is injected in a range of 200-300 sccm, and the high power impulse magnetron sputtering is used to deposit the titanium coating with a thickness in a range of 50-200 nm or directly deposit the titanium coating for 10 min, followed by using the high power impulse magnetron sputtering to deposit the WS₂ coating in a form of a solid lubrication coating with a thickness of 1 μm or directly deposit the WS₂ coating for 55 min to obtain the wear-resistant coating of AlTiN—WS₂. When depositing the titanium coating, parameters of the titanium ion arc target are set as a target current of 25 A, a sputtering power of 1 kilowatt (KW), a pulse frequency of 1000 Hz, a pulse width of 100 microseconds (s), and a depositing time of 10 min. When depositing the WS₂ coating, parameters are set as a target current is set as 8 A, a sputtering power of 1.5 KW, a pulse frequency of 1000 Hz, a pulse width of 300 μs, a bias voltage of the substrate of 50 V and a depositing time of 55 min.

The following will further elaborate on the disclosure in conjunction with specific embodiments.

### Embodiment 1

The coating preparation process is as follows:
(1) a stainless steel is selected as the substrate to be processed. First, the stainless steel is put into an acetone solution and an ethyl alcohol solution to ultrasonically clean for 20 minutes to remove the oil stain on the surface of the stainless steel, thereby obtaining a cleaned stainless steel, then the cleaned stainless steel is ultrasonically cleaned by using a deionized water for 4 times and dried to obtain a preprocessed substrate, and the preprocessed substrate is disposed on a sample holder.
(2) the sample holder provided with the preprocessed substrate is put into a vacuum chamber, then pressure of the vacuum chamber is extracted below 6×10³ pascals (Pa). After the extracting, the vacuum chamber is heat to stabilize a temperature of the vacuum chamber at 100° C.
(3) after the stabilization, the titanium ion arc target is used and a target current is set to 60 amperes (A), an argon gas is injected with 50 standard cubic centimeters per minute (sccm) into the vacuum chamber and a bias voltage of the preprocessed substrate is set to 800 V. Then, the titanium ion cleaning is performed on the preprocessed substrate for 3 min to obtain the cleaned substrate.
(4) after performing the titanium ion cleaning, a bias voltage of the cleaned substrate is set to 300 V, a titanium transition coating is deposited on the cleaned substrate for 30 min by using a multi-arc ion plating to obtain a deposited substrate.
(5) the AlTi alloy ion arc target is used, and a target current is set to 60 A, the argon gas is injected with 20 sccm and a nitrogen gas with 320 sccm into the vacuum chamber, and a bias voltage of the deposited substrate is set to 150 V. Then, the AlTiN coating is deposited in a form of metal nitride coating for 170 min on the deposited substrate to obtain the AlTiN coating substrate.
(6) the temperature of the vacuum chamber is reduced to 100° C., the nitrogen gas is stopped to inject, the argon gas is injected into the vacuum chamber with 300 sccm, and the high power impulse magnetron sputtering is used to deposit the titanium coating. The parameters of the titanium ion arc target (i.e. the titanium target) are set as a target current of 25 A, a sputtering power of 1 KW, a pulse frequency of 1000 Hz, a pulse width of 100 μs, and a depositing time of 10 min.
(7) then the high power impulse magnetron sputtering is used to deposit the WS₂ coating. When depositing the WS₂ coating, the parameters are set as a target current is set as 8 A, a sputtering power of 1.5 KW, a pulse frequency of 1000 Hz, a pulse width of 300 μs, a bias of the substrate of 50 V and a depositing time of 55 min.
(8) After the coating preparation is completed, the power is turned off and the gas is stopped to inject, the sample holder is removed from the vacuum chamber when the temperature drops below 60° C.

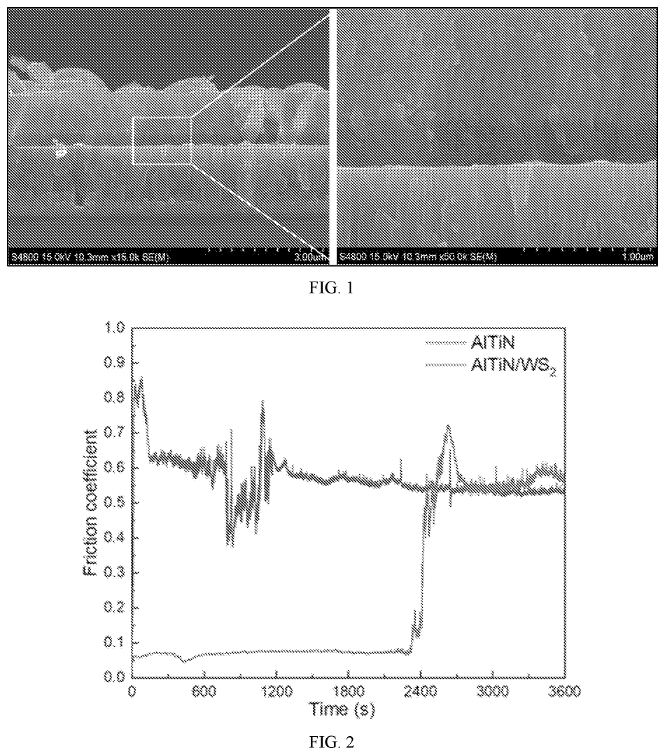

The wear-resistant coating of AlTiN—WS₂ with the low friction coefficient prepared in the embodiment 1 is cross-sectional analyzed by using a scanning electron microscope (SEM), and the results are shown in FIG. 1. The transition coating (i.e. titanium transition coating) is uniform and flat, and the structure of the AlTiN coating and the WS₂ coating can be clearly seen. The third coating is the AlTiN coating, which is used to protect the substrate and improve wear resistance, and the structure of the third coating shows typical columnar crystal growth with coarse grains. The second coating is Ti coating, with a thickness of approximately 200 μm, between the AlTiN coating and the WS₂ coating, the second coating is mainly used to improve the bonding strength between the AlTiN coating and the WS₂ coating. The top coating is the WS₂ coating, which has a dense organizational structure and small grains, mainly playing a role in lubrication and improving the friction and wear performance of the coating.

### Comparative Example 1

### The Coating Preparation Process is as Follows:

(1) a stainless steel is selected as the substrate to be processed. First, the stainless steel is put into an acetone solution and an ethyl alcohol solution to ultrasonically clean for 20 minutes to remove the oil stain on the surface of the stainless steel, thereby obtaining a cleaned stainless steel, then the cleaned stainless steel is ultrasonically cleaned by using a deionized water for 4 times and dried to obtain a preprocessed substrate, and the preprocessed substrate is disposed on a sample holder.
(2) the sample holder provided with the preprocessed substrate is put into a vacuum chamber, then pressure of the vacuum chamber is extracted below 6×10⁻³ Pa, after the extracting, the vacuum chamber is heat to stabilize a temperature of the vacuum chamber at 100° C.
(3) after the stabilization, the titanium ion arc target is used and a target current is set to 60 A, an argon gas is injected with 50 sccm into the vacuum chamber and a bias voltage of the preprocessed substrate is set to 800 V. Then, the titanium ion cleaning is performed on the preprocessed substrate for 3 min to obtain the cleaned substrate.
(4) after performing the titanium ion cleaning, a bias voltage of the cleaned substrate is set to 300 V, a titanium transition coating is deposited on the cleaned substrate by using a multi-arc ion plating for 30 min to obtain a deposited substrate.
(5) the AlTi alloy ion arc target is used, and a target current is set to 60 A, the argon gas is injected with 20 sccm and a nitrogen gas with 320 sccm into the vacuum chamber, and a bias voltage of the deposited substrate is set to 150 V. Then, the AlTiN coating is deposited in a form of metal nitride coating for 170 min on the deposited substrate to obtain the AlTiN coating substrate.
(6) After the coating preparation is completed, the power is turned off and the gas is stopped to inject, the sample holder is removed from the vacuum chamber when the temperature drops below 60° C.

The device used is the same as embodiment 1, and the preparation method is basically the same as the steps (1)-(5) of embodiment 1. The wear-resistant coatings in comparative example 1 has not been coated with WS₂ coating.

The friction and wear tests are conducted on the AlTiN coating prepared in comparative example 1 and the AlTiN—WS₂ composite coating prepared in embodiment 1. The specific friction and wear test parameters are to use GCr15 steel balls with a friction pair diameter of 10 mm in the atmosphere, a load of 10 N is applied, the length of the wear mark on the coatings is 5 mm, and the friction frequency is linearly reciprocating for one hour with a friction frequency of 5 Hz. In addition, a compare test with a friction under a load of 5 N and a relative friction frequency of 2 Hz is conducted.

The results are as shown in FIG. 2, the friction coefficient of the AlTiN coating initially started at 0.8, decreased to 0.63 after 150 seconds, and then decreased to 0.4 after maintaining 0.63 for a period of time. This situation occurs because as the friction time increases, the amount of debris also increases and accumulates in the wear marks. When the steel ball rubs again, the debris acts as a filler between the coating and the steel ball, reducing the contact area and causing the friction coefficient to decrease. When the debris is worn through, the friction coefficient rebounds to around 0.6. The friction coefficient of the AlTiN—WS₂ composite coating remained stable at around 0.07 before 40 minutes, indicating that the WS₂ coating formed a lubricating transfer film on the steel ball and sustainable lubrication between the WS₂ coating and the steel ball. However, the friction coefficient of the AlTiN—WS₂ composite coating suddenly increased to 0.72 between 2400 and 2600 seconds, which may be due to the wearing of the top coating of the WS₂ coating, thereby causing the steel ball starting to rub against the AlTiN coating, resulting in a sudden increase in the friction coefficient. Subsequently, the friction coefficient of AlTiN—WS₂ composite coating decreased steadily to around 0.6.

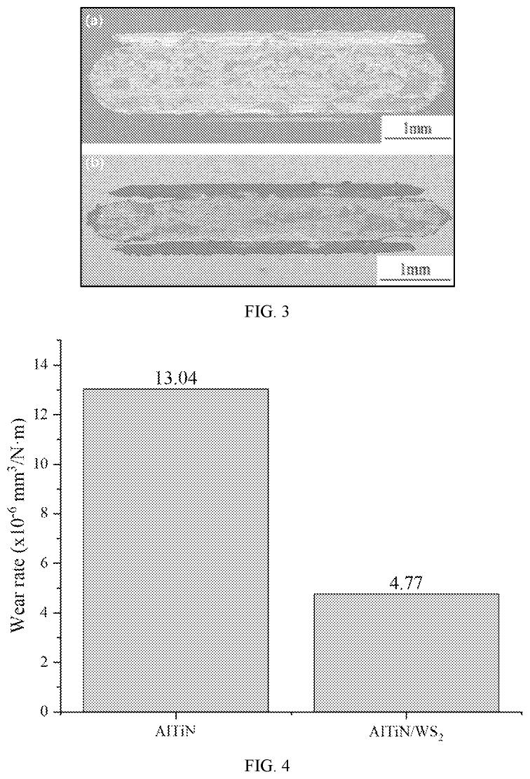

A grinding scar morphology diagram is as shown in FIG. 3, at the same magnification, the wear scar width of the AlTiN coating is significantly wider than that of the AlTiN—WS₂ composite coating, and the wear scar of the AlTiN coating leans towards one side, and the AlTiN—WS₂ composite coating is ground more uniformly without any bias towards one side.

A wear rate is as shown in FIG. 4, the wear rate of the AlTiN—WS₂ composite coating is much lower than that of the AlTiN coating. The wear rate of the AlTiN—WS₂ composite coating is 4.77×10⁻⁶ mm³/(N·m), the wear rate of the AlTiN coating is 13.04×10⁻⁶ mm³/(Nm), and the wear rate of the AlTiN coating is 2.6 times that of the AlTiN—WS₂ composite coating. According to the wear marks of the AlTiN—WS₂ composite coating, it can be seen that during the friction process, the WS₂ coating not only plays a lubricating role but also bears partial wear. When the steel ball contacts the AlTiN coating, it is resisted by the high wear resistance of the AlTiN coating, thereby reducing the wear of the composite coating to protect the substrate.

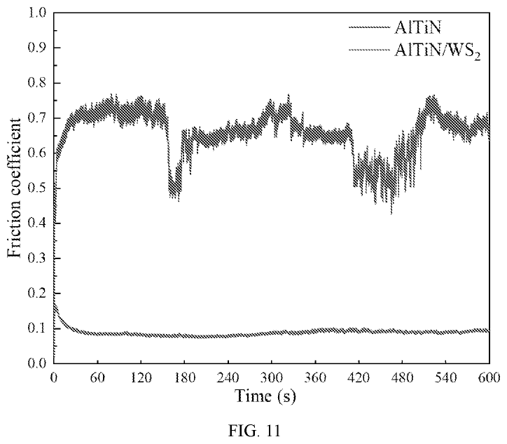

The friction coefficient and wear rate obtained from embodiment 1 and comparative example 1 under the load of 5 N and the friction frequency of 2 Hz are shown in FIG. 10-11.

### Embodiment 2

At present, the coating on the needle rods of the sewing machines is a diamond-like carbon (DLC) coating, which has good self-lubricating, wear resistance, and chemical stability. However, the DLC coating has the problem of low heat resistance temperature. Moreover, the DLC coating is a metastable amorphous carbon coating composed of a mixture of SP² hybrid bonds (graphite phase) and SP³ hybrid bonds (diamond phase), which transforms from graphite phase to diamond phase at high temperatures, affecting stability. Therefore, the wear-resistant coating of AlTiN—WS₂ with the low friction coefficient prepared by the disclosure is applied to the needle rods of the sewing machine.

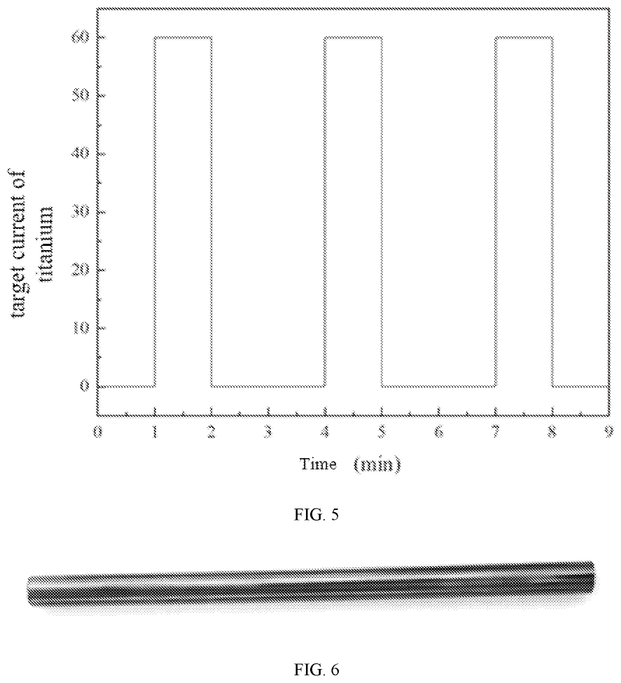

The preparation process of the wear-resistant coating of AlTiN—WS₂ with the low friction coefficient is as follow:
(1) a needle rod of the sewing machine is selected as the substrate to be processed. First, the needle rod of the sewing machine is put into a degreasing cleaning solution to ultrasonically clean for 10-30 minutes to remove the oil stain on the surface of the needle rod of the sewing machine, thereby obtaining a cleaned needle rod, then the cleaned needle rod is ultrasonically cleaned by using a deionized water for 4 times and dried with hot air to obtain a preprocessed substrate, and the preprocessed substrate is disposed on a sample holder.
(2) the sample holder provided with the preprocessed substrate is put into a vacuum chamber, then pressure of the vacuum chamber is extracted below 7×10⁻³ Pa, after the extracting, the vacuum chamber is heat to stabilize a temperature of the vacuum chamber at 100° C.
(3) after the stabilization, the titanium ion arc target is used and a target current is set to 60 A, an argon gas is injected with 50 sccm into the vacuum chamber and a bias voltage of the preprocessed substrate is set to 800 V, the titanium ions are used for metal ion cleaning of the needle rods (i.e. the preprocessed substrate). The working time of the titanium ion arc target is set as turning on for 1 minute and turning off for 2 minutes, and the working time of the titanium ion arc target is shown in FIG. 5.
(4) after performing the titanium ion cleaning, a bias voltage of the cleaned substrate is set to 300 V, a titanium transition coating with a thickness of 300 nm is deposited on the cleaned substrate by using a multi-arc ion plating to obtain a deposited substrate. Then the AlTi alloy ion arc target is used, a nitrogen gas with 320 sccm is injected into the vacuum chamber and a bias voltage of the deposited substrate is set to 100 V. Then the AlTiN coating is deposited in a form of metal nitride coating with a thickness of 1.5 μm on the deposited substrate to obtain the AlTiN coating substrate.
(5) the nitrogen gas is stopped to inject, the argon gas is injected into the vacuum chamber with 300 sccm, and the high power impulse magnetron sputtering is used to deposit the titanium transition coating with a thickness of 200 nm, followed by using the high power impulse magnetron sputtering to deposit the WS₂ solid lubrication coating with a thickness of 1 μm.
(6) After the coating preparation is completed, the power is turned off and the gas is stopped to inject, the sample holder is removed from the vacuum chamber when the temperature drops below 60° C. The appearance is shown in FIG. 6.

### Comparative Example 2

### The Preparation Process is as Follows:

(1) a needle rod of the sewing machine is selected as the substrate to be processed. First, the needle rod of the sewing machine is put into a degreasing cleaning solution to ultrasonically clean for 10-30 minutes to remove the oil stain on the surface of the needle rod of the sewing machine, thereby obtaining a cleaned needle rod, then the cleaned needle rod is ultrasonically cleaned by using a deionized water for 4 times and dried with hot air to obtain a preprocessed substrate, and the preprocessed substrate is disposed on a sample holder.
(2) the sample holder provided with the preprocessed substrate is put into a vacuum chamber, then pressure of the vacuum chamber is extracted below 7×10⁻³ Pa, after the extracting, the vacuum chamber is heat to stabilize a temperature of the vacuum chamber at 100° C.
(3) after the stabilization, the titanium ion arc target is used and, a target current is set to 60 A, an argon gas is injected with 50 sccm into the vacuum chamber and a bias voltage of the preprocessed substrate is set to 800 V, the titanium ions are used for metal ion cleaning of the needle rods. The working time of the titanium ion arc target is set as turning on for 1 minute and turning off for 2 minutes, and the working time of the titanium ion arc target is shown in FIG. 5.
(4) after performing the titanium ion cleaning, a bias voltage of the cleaned substrate is set to 300 V, a titanium transition coating with a thickness of 300 nm is deposited on the cleaned substrate by using a multi-arc ion plating to obtain a deposited substrate. Then the AlTi alloy ion arc target is used, a nitrogen gas with 320 sccm is injected into the vacuum chamber and a bias voltage of the deposited substrate is set to 100 V. Then the AlTiN coating is deposited in a form of metal nitride coating with a thickness of 1.5 μm on the deposited substrate to obtain the AlTiN coating substrate.
(5) After the coating preparation is completed, the power is turned off and the gas is stopped to inject, the sample holder is removed from the vacuum chamber when the temperature drops below 60° C.

### Comparative Example 3

### The Preparation Process is as Follows:

(1) a needle rod of the sewing machine is selected as the substrate to be processed. First, the needle rod of the sewing machine is put into a degreasing cleaning solution to ultrasonically clean for 10-30 minutes to remove the oil stain on the surface of the needle rod of the sewing machine, thereby obtaining a cleaned needle rod, then the cleaned needle rod is ultrasonically cleaned by using a deionized water for 4 times and dried with hot air to obtain a preprocessed substrate, and the preprocessed substrate is disposed on a sample holder.
(2) the sample holder provided with the preprocessed substrate is put into a vacuum chamber, then pressure of the vacuum chamber is extracted below 7×10⁻³ Pa, after the extracting, the vacuum chamber is heat to stabilize a temperature of the vacuum chamber at 100° C.
(3) after the stabilization, the titanium ion arc target is used and a target current is set to 60 A, an argon gas is injected with 50 sccm into the vacuum chamber and a bias voltage of the preprocessed substrate is set to 800 V, the titanium ions are used for metal ion cleaning of the needle rods. The working time of the titanium ion arc target is set as turning on for 1 minute and turning off for 2 minutes, and the working time of the titanium ion arc target is shown in FIG. 5.
(4) the nitrogen gas is stopped to inject, the argon gas is injected into the vacuum chamber with 300 sccm, and the high power impulse magnetron sputtering is used to deposit the titanium transition coating with a thickness of 200 nm, followed by using the high power impulse magnetron sputtering to deposit the WS₂ solid lubrication coating with a thickness of 1 μm.
(5) After the coating preparation is completed, the power is turned off and the gas is stopped to inject, the sample holder is removed from the vacuum chamber when the temperature drops below 60° C.

The device used for comparative example 2 is the same as embodiment 2, and the method is basically the same as embodiment 2. In the comparative example 2, the AlTiN solid coating is only prepared on the needle rod, without WS₂ solid lubrication coating.

The device used for comparative example 3 is the same as embodiment 2, and the method is basically the same as embodiment 2. In the comparative example 3, the AlTiN solid coating dose not deposited on the surface of the needle rod, only the WS₂ solid lubrication coating is deposited on the surface of the needle rod.

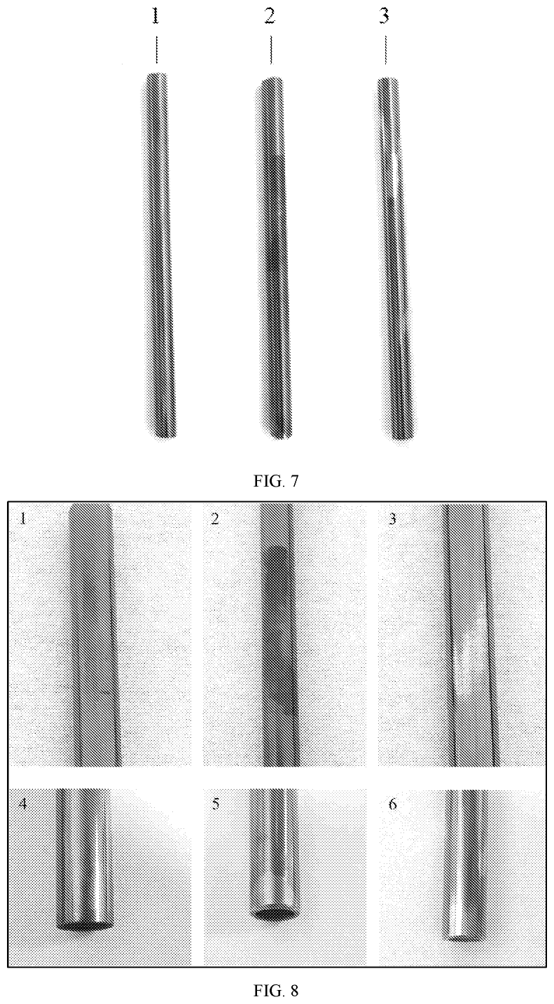

By using a commercial sewing machine, running-in tests are conducted on the needle rods in embodiment 2, comparative example 2, and comparative example 3 without adding any form of lubricating material. During the running-in tests, the sewing machine speed is 4000 r/min and worked for 2 hours. FIG. 7 shows the photos of embodiment 2, comparative example 2 and comparative example 3 after the running-in tests. As shown in FIG. 7, it can be seen that all samples of three needle rods showed varying degrees of wear after the running-in tests. The friction areas of the needle rods are mainly concentrated in the upper and lower parts. The wear marks on the upper and middle parts of 2 needle rod are quite severe, and some parts of the lower friction area have fallen off, exposing the metal surface of the needle rod. The wear marks on 1 needle rod are relatively shallow, and the presence of wear marks is almost invisible. 3 needle rod showed significant wear on both the upper and lower parts, revealing large areas of the needle rod substrate.

FIG. 8 shows photos of local wears after the running-in tests for embodiment 2, comparative example 2, and comparative example 3. From FIG. 8, it can be seen that the wear in embodiment 2 of the disclosure is relatively light, and slight wear occurs at the positions on the needle rod that form relative friction with the upper and lower sleeves. The wear on comparative example 2 is more severe, and there is a large area of coating detachment at the position on the needle rod that form relative friction with the upper sleeve. For the needle rod in comparative example 3, both two positions on the needle rod can clearly see that a large amount of the WS₂ coating is almost worn through, revealing a silver white metal substrate, indicating that a single WS₂ coating is prone to wear during operation.

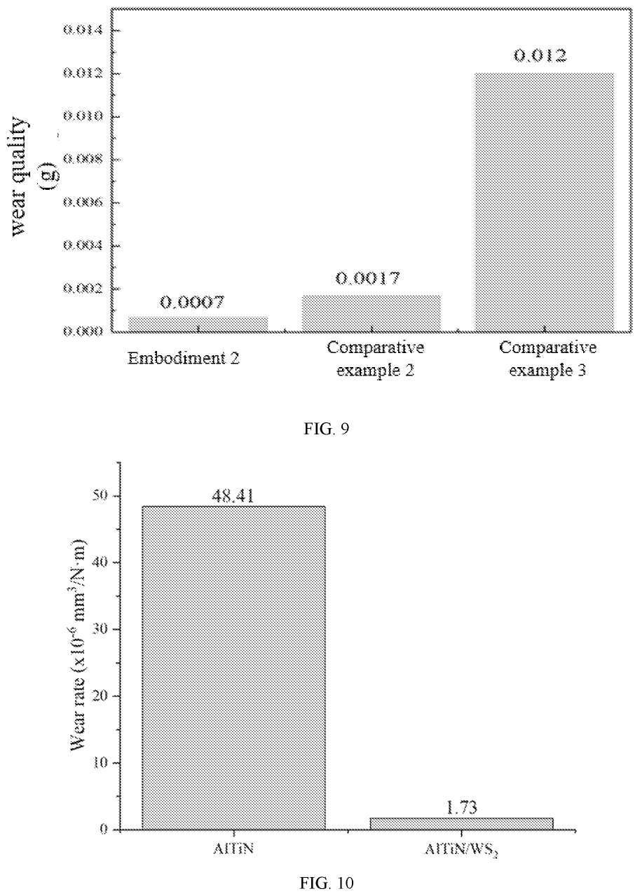

FIG. 9 shows a wear quality after running-in tests in the embodiment 2, the comparative example 2 and the comparative example 3.

The above embodiments are only a description of the specific embodiments of disclosure, and do not limit the scope of the disclosure. Without departing from the design spirit of the disclosure, all variations and improvements made by those skilled in the art to the technical solution of the disclosure should fall within the scope of protection determined by the claims of the disclosure.

1. A preparation method for a wear-resistant coating of aluminum titanium nitride-tungsten disulfide (AlTiN—WS₂), comprising:
(1) performing a titanium ion cleaning on a preprocessed substrate by using a titanium ion arc target to obtain a cleaned substrate;
(2) depositing a titanium transition coating on the cleaned substrate by using a multi-arc ion plating to obtain a deposited substrate;
(3) depositing an aluminum titanium nitride (AlTiN) coating on the deposited substrate by using an AlTi alloy ion arc target to obtain an AlTiN coating substrate; and
(4) depositing a titanium coating and a tungsten disulfide (WS₂) coating respectively on the AlTiN coating substrate by using an impulse magnetron sputtering to obtain the wear-resistant coating of AlTiN—WS₂.

2. The preparation method as claimed in claim 1, wherein the performing a titanium ion cleaning on a preprocessed substrate by using a titanium ion arc target to obtain a cleaned substrate comprises:
putting the preprocessed substrate into a vacuum chamber, then extracting pressure of the vacuum chamber below 7×10⁻³ pascals (Pa), after the extracting, heating the vacuum chamber to stabilize a temperature of the vacuum chamber in a range of 100-300° C., followed by using the titanium ion arc target with a set target current of 60 amperes (A), injecting an argon gas in a range of 50-100 standard cubic centimeter per minute (sccm) and setting a bias voltage of the preprocessed substrate in a range of 600-800 voltages (V), and performing the titanium ion cleaning on the preprocessed substrate for 3-5 minutes (min) to obtain the cleaned substrate.

3. The preparation method as claimed in claim 1, wherein the depositing a titanium transition coating on the cleaned substrate by using a multi-arc ion plating to obtain a deposited substrate comprises:
after performing the titanium ion cleaning, setting a bias voltage of the cleaned substrate in a range of 100-300 V, followed by depositing the titanium transition coating with a thickness in a range of 100-500 nanometers (nm) on the cleaned substrate by using the multi-arc ion plating to obtain the deposited substrate.

4. The preparation method as claimed in claim 1, wherein the depositing an AlTiN coating on the deposited substrate by using an AlTi alloy ion arc target to obtain an AlTiN coating substrate comprises:
using the AlTi alloy ion arc target, injecting an argon gas in a range of 20-120 sccm and a nitrogen gas in a range of 200-400 sccm, and setting a bias voltage of the deposited substrate in a range of 50-150 V, and depositing the AlTiN coating in a form of a metal nitride coating with a thickness in a range of 1-3 micrometers (μm) to obtain the AlTiN coating substrate.

5. The preparation method as claimed in claim 1, wherein the depositing a titanium coating and a WS₂ coating respectively on the AlTiN coating substrate by using an impulse magnetron sputtering to obtain the wear-resistant coating of AlTiN—WS₂ comprises:
reducing a temperature of a vacuum chamber to 100° C., stopping injecting a nitrogen gas, injecting an argon gas in a range of 200-300 sccm, and using the impulse magnetron sputtering to deposit the titanium coating with a thickness in a range of 50-200 nm, followed by using the impulse magnetron sputtering to deposit the WS₂ coating in a form of a solid lubrication coating to obtain the wear-resistant coating of AlTiN—WS₂.

6. (canceled)

7. An application method of the wear-resistant coating of AlTiN—WS₂ prepared by the preparation method as claimed in claim 1, comprising:
adding the wear-resistant coating of AlTiN—WS₂ on needle rods of a sewing machine.
